(19) United States
(12) Patent Application Publication
(10) Pub. No.: US 2024/0206054 A1
(43) Pub. Date: Jun. 20, 2024

(54) BENDABLE FLEXIBLE SUBSTRATE AND ELECTRONIC DEVICE

(71) Applicant: Panasonic Intellectual Property Management Co., Ltd., Osaka (JP)

(72) Inventors: Takashi ICHIHARA, Kanagawa (JP); Tatsuji KANNO, Tokyo (JP); Tomohiro UKAI, Tokyo (JP)

(73) Assignee: Panasonic Intellectual Property Management Co., Ltd., Osaka (JP)

(21) Appl. No.: 18/545,504

(22) Filed: Dec. 19, 2023

(30) Foreign Application Priority Data
Dec. 20, 2022 (JP) 2022-203239

(51) Int. Cl. H05K 1/02; H05K 1/14

(52) U.S. Cl. CPC H05K 1/028; H05K 1/0298; H05K 1/147; H01Q 1/2291

(57) ABSTRACT

A base material extends from a first end to a second end. A first conductive pattern is formed from the first end side to the second end side on a surface of the base material. A second conductive pattern (3.3V) and a second conductive pattern (1.8V) are formed from the first end side to the second end side on the surface of the base material and have a shape that is wider than that of the first conductive pattern. The base material can be bent along a bending line C that crosses the base material at a position between the first end and the second end. A slit that intersects the bending line C and that is shorter than the distance between the first end and the second end is arranged inside the second conductive pattern (3.3V) and the second conductive pattern (1.8V).

### BACKGROUND

### 1. Field

The present disclosure relates to flexible substrates and in particular to bendable flexible substrates and electronic devices.

### 2. Description of the Related Art

The demand for flexible substrates that can be bent and stored is increasing as electronic devices become smaller (see, for example, Patent Literature 1).
[Patent Literature 1] PCT International Publication No. WO22/181764

Multiple conductive patterns are formed on the surface of a flexible base material in a flexible substrate. Therefore, the multiple conductive patterns are also bent when the base material is bent. In general, the wider the conductive patterns are, the harder they are to bend. There are parts that are easy to bend and portions that are difficult to bend if the width of the multiple conductive patterns formed on the substrate is not uniform. The base material is likely to be bent obliquely if there are parts that are easy to bend and parts that are difficult to bend. The bending of the substrate in an oblique manner makes it difficult for the end portion of the flexible substrate to be inserted into a connector.

### SUMMARY

In this background, a purpose of the present disclosure is to provide a technology for suppressing the occurrence of bending in an oblique manner even when the width of multiple conductive patterns is not uniform.

A flexible substrate according to one embodiment of the present disclosure includes: a base material that extends from a first end to a second end; a first conductive pattern that is formed from the first end side to the second end side on a surface of the base material; and a second conductive pattern that is formed from the first end side to the second end side on the surface of the base material and that has a shape that is wider than that of the first conductive pattern. The base material can be bent along a bending line that crosses the base material at a position between the first end and the second end, and a slit that intersects the bending line and that is shorter than the distance between the first end and the second end is arranged inside the second conductive pattern.

Another embodiment of the present disclosure also relates to a flexible substrate. This flexible substrate includes: a base material that extends from a first end to a second end; a first conductive pattern that is formed from the first end side to the second end side on a surface of the base material; and a second conductive pattern that is formed from the first end side to the second end side on the surface of the base material and that has a shape that is wider than that of the first conductive pattern. The base material can be bent along a bending line that crosses the base material at a position between the first end and the second end, and the width of the second conductive pattern is narrow at a part intersecting the bending line.

### BRIEF DESCRIPTION OF THE DRAWINGS

Embodiments will now be described, by way of example only, with reference to the accompanying drawings that are meant to be exemplary, not limiting, and wherein like elements are numbered alike in several figures, in which:

FIG. 1 is an exploded perspective view showing a structure of an electronic device according to an embodiment;

FIG. 2 is a front view of the electronic device according to FIG. 1 when viewed from the front side;

FIG. 3 is a front view showing a structure of an antenna module according to FIG. 1;

FIGS. 4A-4D are diagrams showing a structure of a flexible substrate attached to an electronic device;

FIGS. 5A-5B are enlarged views showing a structure of a curved portion according to FIG. 4D; and

FIGS. 6A-6C are enlarged views showing another structure of a curved portion according to FIG. 4D.

### DETAILED DESCRIPTION

The invention will now be described by reference to the preferred embodiments. This does not intend to limit the scope of the present invention, but to exemplify the invention.

A brief description of the present disclosure will be given before a specific description thereof is given. The present embodiment relates to an electronic device provided with a plurality of substrates in the housing. An example of an electronic device is an in-vehicle device or the like that can be mounted in a vehicle, etc. When a plurality of substrates are provided in a housing, it is necessary to electrically connect the plurality of substrates. On the other hand, since miniaturization is required for electronic devices such as in-vehicle devices, the space inside the housing becomes small. Bendable flexible substrates are desirably used when electrically connecting a plurality of substrates under a situation where the space in the housing is small.

As described above, bending in an oblique manner is likely to occur at the time of bending a flexible substrate when the width of a plurality of conductive patterns formed on the flexible substrate is not uniform. The bending in an oblique manner makes it difficult for the end portion of the flexible substrate to be inserted into a connector. It is required to suppress the occurrence of bending in an oblique manner even if the width of the conductive patterns is not uniform. A conductive pattern with a predetermined width, hereinafter referred to as “first conductive pattern”, and a conductive pattern with a width wider than that of the first conductive pattern, hereinafter referred to as “second conductive pattern”, are formed on a flexible substrate according to an exemplary embodiment, and a slit is provided in an area straddling a bending line in the second conductive pattern. With this configuration, the slit makes it easier to bend the second conductive pattern even if the width of the second conductive pattern is large, thereby suppressing the occurrence of bending in an oblique manner.

In the following explanation, “parallel” and “orthogonal” include not only a case of perfect parallelism and perfect orthogonality but also a case of being deviated from parallelism and orthogonality within the margin of error. In addition, “approximately” means being the same in an approximate range.

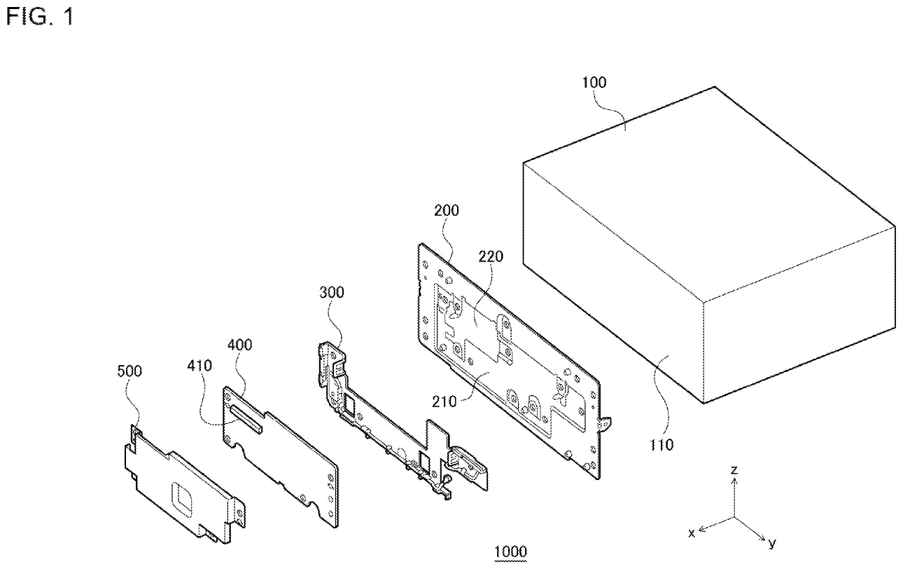

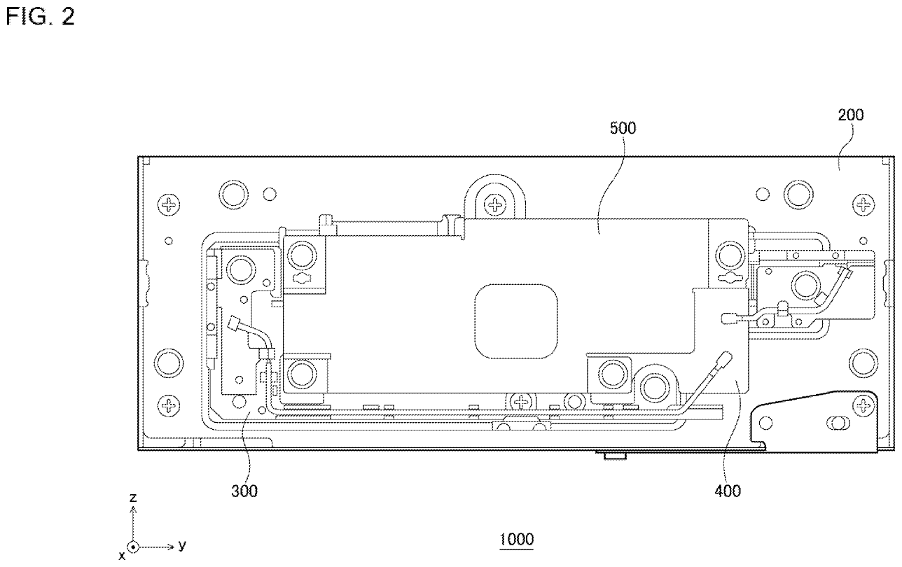

FIG. 1 is an exploded perspective view showing a structure of an electronic device 1000. FIG. 2 is a front view of the electronic device 1000 from the front side. As shown in FIG. 1, an orthogonal coordinate system including an x-axis, a y-axis, and a z-axis is defined. The x-axis and the y-axis are orthogonal to each other. The z-axis is perpendicular to the x-axis and the y-axis and extends in the height direction of the electronic device 1000. The positive direction of each of the x-axis, the y-axis, and the z-axis is defined as the direction of each arrow in FIG. 1, and the negative direction is defined as the opposite direction of the arrow. In this specification, the positive direction of the x-axis may be referred to as “forward” or “front side,” the negative direction of the x-axis as “backward” or “rear side,” the positive direction of the y-axis as “rightward” or “right side,” the negative direction of the y-axis as “leftward” or “left side,” the positive direction of the z-axis as “upward” or “upper side,” and the negative direction of the z-axis as “downward” or “down side.” Therefore, it can be considered that the x-axis extends in the front-back direction, that the y-axis extends in the left-right direction, and that the z-axis extends in the up-down direction.

A housing 100 has a hollow box shape. A circuit, not shown, is for executing various functions of the electronic device 1000 is arranged inside the housing 100. An opening 110 is provided on the front side of the housing 100, and the opening 110 is covered by a front plate 200 having a plate shape. A central portion of the front side surface of the front plate 200 is provided with a fixing portion 210, which is a depression in which an antenna module 300 can be fixed from the front side. A through hole 220 penetrating through the front plate 200 is provided on the upper side of the fixing portion 210 in the front plate 200. The structure of the antenna module 300 is described below. The antenna module 300 has a shape that does not block the through hole 220. A communication substrate 400 is mounted on the front side of the antenna module 300. The communication substrate 400 is mounted with a circuit, not shown, for executing communication via wireless LAN and Bluetooth (registered trademark). The communication substrate 400 blocks the through hole 220 in the front plate 200 when the communication substrate 400 is mounted on the antenna module 300. A first connector 410 is arranged on the front side surface of the communication substrate 400. The communication substrate 400 is covered by a front side cover 500 from the front.

A 2.4 GHz/5 GHz compatible dual-band antenna is used for communication in a 2.4 GHz band for Bluetooth (registered trademark) and communication in a 2.4 GHz/5 GHz band for wireless LAN. An antenna for Bluetooth (registered trademark) and wireless LAN in the 5 GHz band and an antenna for wireless LAN in the 2.4 GHz and 5 GHz bands are conventionally separated from each other and mounted separately. In such a configuration, the individual antennas are plate-shaped components that are easily deformed, and transportation is done in two packages. Further, cable wiring work is required after each antenna is mounted, and it is difficult to evaluate antenna performance until the mounting is completed. Furthermore, a mounting hook for fixing the cable must be provided in the housing when each antenna is mounted on the front side of the housing. By providing the mounting hook in the housing by a cutout process, a through hole is generated in the housing. Due to the through hole, jamming radio waves generated in the vehicle interior can affect the circuitry inside the housing.

In the present embodiment, two antennas are mounted on a resin plate, and an antenna module 300 is provided in which a cable connected to each antenna is attached to the antenna or the resin plate. The modularization increases the strength of the antennas and realizes transportation in one package. Further, cable wiring work after attaching the antenna module 300 to the housing 100 is no longer required. It becomes possible to evaluate the performance of the antennas with the antenna module 300 alone. Further, the circuit inside the housing 100 is less susceptible to jamming radio waves generated in the vehicle interior since there are no through holes in the housing 100 when the cable is attached to the resin plate.

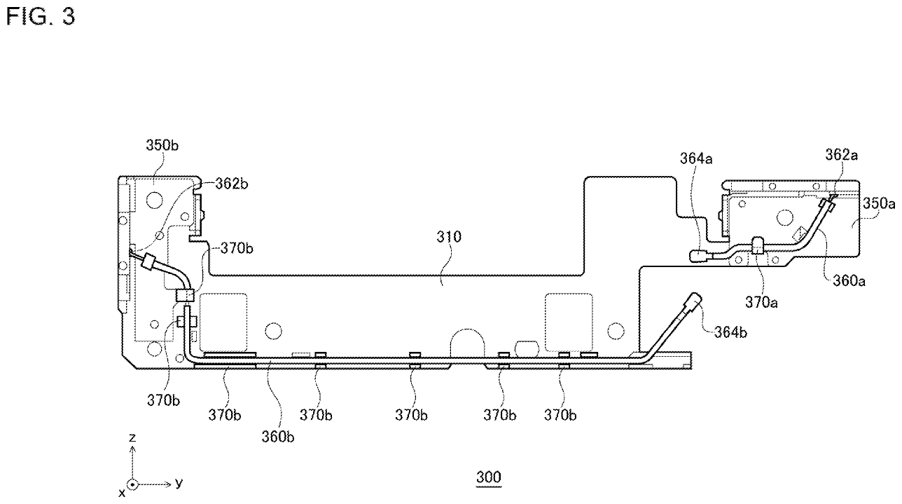

FIG. 3 is a front view of the structure of the antenna module 300. A resin plate 310 has a shape that is longer in the left-right direction than in the up-down direction. The resin plate 310 can be attached to the fixing portion 210 (FIG. 1) of the front plate 200 from the front. A first antenna 350a is provided at the right end on the front side surface of the resin plate 310. The first antenna 350a and the communication substrate 400 (FIG. 1) are connected by a first cable 360a. More specifically, a first cable connection 362a and a first cable terminal 364a are provided at the respective ends of the first cable 360a. The first cable connection 362a is connected to the first antenna 350a, and the first cable terminal 364a is connected to the communication substrate 400. The first cable 360a is attached to a first mounting hook 370a between the first cable connection 362a and the first cable terminal 364a.

A second antenna 350b is provided at the left end on the front side surface of the resin plate 310. The second antenna 350b and the communication substrate 400 (FIG. 1) are connected by a second cable 360b. More specifically, a second cable connection 362b and a second cable terminal 364b are provided at the respective ends of the second cable 360b. The second cable connection 362b is connected to the second antenna 350b, and the second cable terminal 364b is connected to the communication substrate 400. The second cable 360b is attached to a second mounting hook 370b between the second cable connection 362b and the second cable terminal 364b.

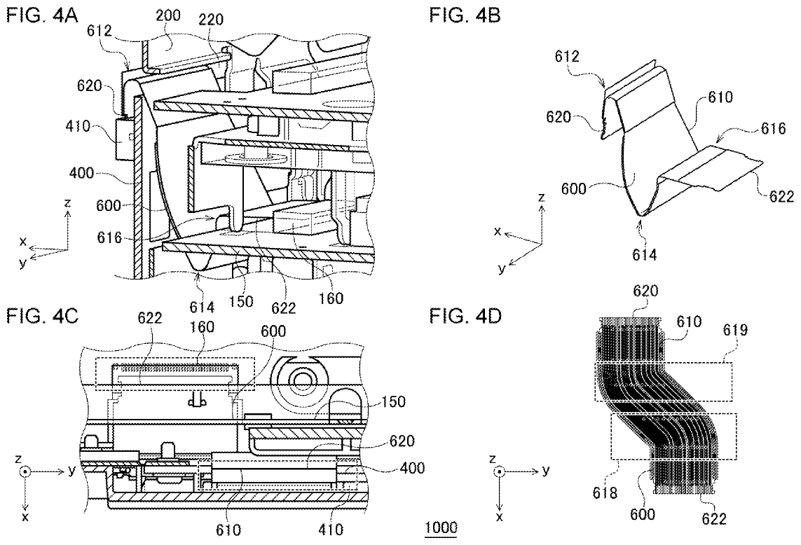

Wiring work in the electronic device 1000 is performed in order to connect the communication substrate 400 and the substrate (not shown) in the housing 100 since the antennas are modularized by the antenna module 300. FIGS. 4A-4D show the structure of a flexible substrate 600 attached to the electronic device 1000. FIG. 4A shows a structure when viewed from the inside of the housing 100 toward the front side. A substrate 150 spreading in the x-y plane is arranged inside the housing 100. On the upper side surface of the substrate 150, a circuit (not shown) for executing the process of the electronic device 1000 is mounted, and a second connector 160 is arranged. As described above, the front plate 200 is arranged on the front side of the housing 100, and the communication substrate 400 is arranged on the front side of the front plate 200 so as to block the through hole 220. The communication substrate 400 and the substrate 150 are connected by the flexible substrate 600. When the communication substrate 400 is referred to as “first substrate,” the substrate 150 is referred to as “second substrate.”

FIG. 4B shows flexible substrate 600 in the state of FIG. 4A. A base material 610 of the flexible substrate 600 is a flexible resin film and extends from a first end 620 to a second end 622. The first end 620 is connected to the first connector 410 of the communication substrate 400, and the second end 622 is connected to the second connector 160 of the substrate 150. The base material 610 extends toward the upper side along the communication substrate 400 and is bent toward the down side at a 180-degree bending part 612 when the first end 620 is connected to the first connector 410. The bent base material 610 extends toward the down side and the rear side through the through hole 220 and is bent toward the upper side at a 180-degree bending part 614. The bent base material 610 extends toward the upper side and the rear side, is bent toward the rear side at a 90-degree bending part 616, and extends toward the rear side along the upper side surface of the substrate 150. The second end 622, which is a rear end of the base material 610, is connected to the second connector 160. The flexible substrate 600 is bent approximately 180 degrees at the 180-degree bending part 612 and at the 180-degree bending part 614 and is bent approximately 90 degrees at the 90-degree bending part 616 since the flexible substrate 600 needs to be stored in a space between the communication substrate 400 and the substrate 150.

FIG. 4C is a top view of the state in FIG. 4A. The first end 620 is connected to the first connector 410 of the communication substrate 400, and the second end 622 is connected to the second connector 160 of the substrate 150. The first connector 410 and the second connector 160 are displaced in the left-right direction. FIG. 4D is a top view showing a structure obtained before bending the flexible substrate 600. Since the first connector 410 and the second connector 160 are arranged being deviated in the left-right direction, the base material 610 is curved at a curved part 618 and a curved part 619 between the first end 620 and the second end 622. In the base material 610 having two curves, deviation may occur at the first end 620 and the second end 622 depending on dimensional accuracy. In the base material 610 having three curves, misalignment may occur at the first end 620 and the second end 622.

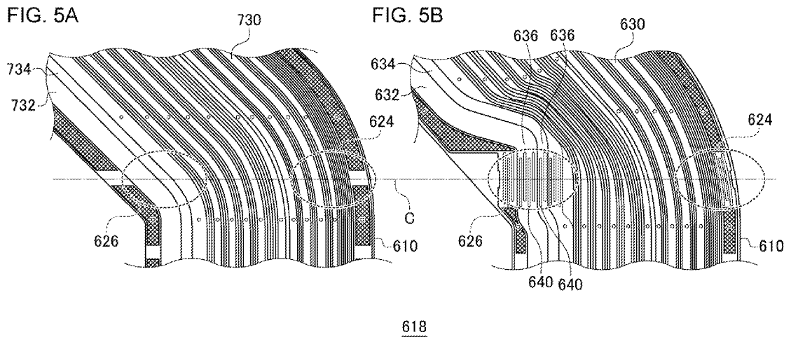

FIG. 5A to 5B are enlarged views of the structure of the curved part 618. A bending line C that crosses the base material 610 is arranged at the curved part 618 at a position between the first end 620 and the second end 622 of the base material 610. The base material 610 is bendable along the bending line C. The part of the base material 610 bent along the bending line C included in the curved part 618 corresponds to the 180-degree bending part 614 shown in FIG. 4C. The part of the base material 610 bent at the curved part 619 shown in FIG. 4D corresponds to the 180-degree bending part 612 shown in FIG. 4C.

FIG. 5A shows a structure to be compared with that according to the present disclosure. A plurality of conductive patterns are formed by copper foil or the like from the first end 620 side to the second end 622 side on the surface of the base material 610. The plurality of conductive patterns are arranged side by side. The plurality of conductive patterns include a first conductive pattern 730, a second conductive pattern (3.3V) 732, and a second conductive pattern (1.8V) 734. The second conductive pattern (3.3V) 732 is used for applying a voltage of 3.3V, and the second conductive pattern (1.8V) 734 is used for applying a voltage of 1.8V. The second conductive pattern (3.3V) 732 and the second conductive pattern (1.8V) 734 have a shape that is wider than that of the first conductive pattern 730. The wider the width of the conductive patterns, the greater the amount of copper foil used, thus increasing the hardness of the conductive patterns.

Therefore, the hardness of the second conductive pattern (3.3V) 732 and the hardness of the second conductive pattern (1.8V) 734 are higher than that of the first conductive pattern 730. Such a difference in hardness makes it easier for bending in an oblique manner to occur due to bending that deviates from the bending line C when the base material 610 is bent along the bending line C.

The first conductive pattern 730, the second conductive pattern (3.3V) 732, and the second conductive pattern (1.8V) 734 extend according to the shape of the base material 610 and curve along the curved shape of the base material 610. When the conductive patterns are curved at the curved part 618, bending in an oblique manner is even more likely to occur at the time of bending at the bending line C.

FIG. 5B shows a structure according to the present disclosure. The base material 610 and the bending line C are the same as those in FIG. 5A. The plurality of conductive patterns include a first conductive pattern 630, a second conductive pattern (3.3V) 632, and a second conductive pattern (1.8V) 634. The first conductive pattern 630 corresponds to the first conductive pattern 730, the second conductive pattern (3.3V) 632 corresponds to the second conductive pattern (3.3V) 732, and the second conductive pattern (1.8V) 634 corresponds to the second conductive pattern (1.8V) 734. Therefore, the second conductive pattern (3.3V) 632 and the second conductive pattern (1.8V) 634 have a shape that is wider than that of the first conductive pattern 630.

In order to suppress the occurrence of bending in an oblique manner, a plurality of slits 640 intersecting the bending line C are arranged inside each of the second conductive pattern (3.3V) 632 and the second conductive pattern (1.8V) 634. The slits 640 are parts not formed of copper foil, etc., and that have lower hardness than that of copper foil, etc. The arrangement of the slits 640 in the second conductive pattern (3.3V) 632 and the second conductive pattern (1.8V) 634 lowers the hardness of the second conductive pattern (3.3V) 632 and the hardness of the second conductive pattern (1.8V) 634 compared to when the slits 640 are not arranged. Thereby, the hardness difference between the first conductive pattern 630 and the second conductive pattern (1.8V) 634 is reduced. By reducing the difference in hardness, the occurrence of bending in an oblique manner is suppressed.

On the other hand, the presence of the slits 640 increases the electrical resistance of the second conductive pattern (3.3V) 632 and the electrical resistance of the second conductive pattern (1.8V) 634. The length of the slits 640 is made to be shorter than the distance between the first end 620 and the second end 622, for example, one-tenth of the distance between the first end 620 and the second end 622 or less. By limiting the length of the slits 640, the increase in the electrical resistance of the second conductive pattern (3.3V) 632 and the electrical resistance of the second conductive pattern (1.8V) 634 is suppressed.

The first conductive pattern 630 is curved along the curved shape of the base material 610 in the same way as in the first conductive pattern 730. On the other hand, the second conductive pattern (3.3V) 632 and the second conductive pattern (1.8V) 634 have a straight line shape in a partial section across the bending line C and straddle the bending line C at a substantially right angle. The length of the partial section is set to be the length of the slits 640 or longer. The occurrence of bending in an oblique manner is suppressed since the second conductive pattern (3.3V) 632 and the second conductive pattern (1.8V) 634 are not inclined with respect to the bending line C. The first conductive pattern 630, the second conductive pattern (3.3V) 632, and the second conductive pattern (1.8V) 634 at the curved part 619 may have the same structure as those in FIG. 5D.

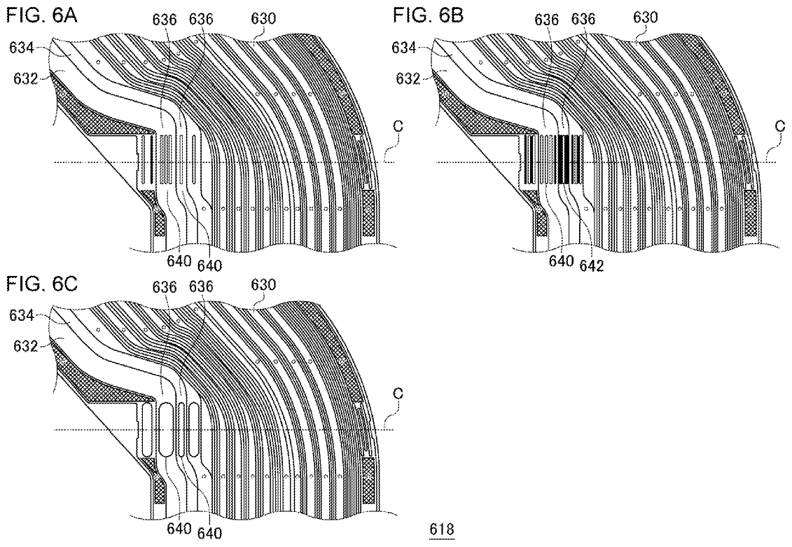

FIG. 6A to 6C are enlarged views of another structure of the curved part 618. FIGS. 6A to 6C are shown in the same manner as FIG. 5B. FIG. 6A has a different number of slits 640 compared to that in FIG. 5B. The second conductive pattern (1.8V) 634 in FIG. 6B does not have slits 640 and has a narrow part 642 arranged in a section that intersects the bending line C, for example, the partial section described above. The narrow part 642 is a part whose width is narrower than that of other parts. The narrow part 642 may be arranged in the second conductive pattern (3.3V) 632. In that case, slits 640 do not need to be arranged. In FIG. 6C, the plurality of slits 640 in FIG. 5B are combined into one.

According to the present disclosure, the plurality of conductive patterns can have similar hardness since the slits 640 intersecting the bending line C are arranged in the second conductive pattern (3.3V) 632 and the second conductive pattern (1.8V) 634, which are wider than the first conductive pattern 630. The occurrence of bending in an oblique manner can be suppressed even when the width of the plurality of conductive patterns is not uniform since the hardness of the plurality of conductive patterns is similar. Further, an increase in the electrical resistance can be suppressed since the slits 640 are made shorter than the distance between the first end 620 and the second end 622. Further, the plurality of conductive patterns can have similar hardness since the narrow part 642 is arranged in the second conductive pattern (3.3V) 632 or the second conductive pattern (1.8V) 634, which are wider than the first conductive pattern 630. Also, the occurrence of bending in an oblique manner can be suppressed since the first conductive pattern 630 is curved along the curved shape of the base material 610 while the second conductive pattern (3.3V) 632 and the second conductive pattern (1.8V) 634 have a straight line shape in a partial section across the bending line C.

The outline of one aspect of the present disclosure is as follows. A flexible substrate (600) according to an embodiment of the present disclosure includes: a base material (610) that extends from a first end (620) to a second end (622); a first conductive pattern (630) that is formed from the first end (620) side to the second end (622) side on a surface of the base material (610); and a second conductive pattern (632, 634) that is formed from the first end (620) side to the second end (622) side on the surface of the base material (610) and that has a shape that is wider than that of the first conductive pattern 630. The base material (610) can be bent along a bending line C that crosses the base material (610) at a position between the first end (620) and the second end (622), and a slit (640) that intersects the bending line C and that is shorter than the distance between the first end (620) and the second end (622) is arranged inside the second conductive pattern (632, 634).

Another embodiment of the present disclosure also relates to a flexible substrate (600). This flexible substrate (600) includes: a base material (610) that extends from a first end (620) to a second end (622); a first conductive pattern (630) that is formed from the first end (620) side to the second end (622) side on a surface of the base material (610); and a second conductive pattern (632, 634) that is formed from the first end (620) side to the second end (622) side on the surface of the base material (610) and that has a shape that is wider than that of the first conductive pattern 630. The base material (610) can be bent along a bending line C that crosses the base material (610) at a position between the first end (620) and the second end (622), and the width of the second conductive pattern (632, 634) is narrow at a part intersecting the bending line C.

The base material (610) may be curved at a part between the first end (620) and the second end (622), and the base material (610) may have the bending line C at the curved part. The first conductive pattern (630) may be curved along the curved shape of the base material (610), and the second conductive pattern (632, 634) may have a straight line shape in a partial section across the bending line C.

A flexible substrate (600), a first substrate (400) connected to the first end (620) of the flexible substrate (600), and a second substrate (150) connected to the second end (622) of the flexible substrate (600) may be provided.

Described above is an explanation based on the embodiments of the present disclosure. The embodiments are intended to be illustrative only, and it will be obvious to those skilled in the art that various modifications to a combination of constituting elements or processes in the embodiments could be developed and that such modifications also fall within the scope of the present disclosure.

While various embodiments have been described herein above, it is to be appreciated that various changes in form and detail may be made without departing from the spirit and scope of the invention(s) presently or hereafter claimed.

### CROSS-REFERENCE TO RELATED APPLICATION

This application is based upon and claims the benefit of priority from the prior Japanese Patent Application No. 2022-203239, filed on Dec. 20, 2022, the entire contents of which are incorporated herein by reference.

What is claimed is:

1. A flexible substrate comprising:
a base material that extends from a first end to a second end;
a first conductive pattern that is formed from the first end side to the second end side on a surface of the base material; and
a second conductive pattern that is formed from the first end side to the second end side on the surface of the base material and that has a shape that is wider than that of the first conductive pattern,
wherein the base material can be bent along a bending line that crosses the base material at a position between the first end and the second end, and
wherein a slit that intersects the bending line and that is shorter than the distance between the first end and the second end is arranged inside the second conductive pattern.

2. A flexible substrate comprising:
a base material that extends from a first end to a second end;
a first conductive pattern that is formed from the first end side to the second end side on a surface of the base material; and
a second conductive pattern that is formed from the first end side to the second end side on the surface of the base material and that has a shape that is wider than that of the first conductive pattern,
wherein the base material can be bent along a bending line that crosses the base material at a position between the first end and the second end, and
wherein the width of the second conductive pattern is narrow at a part intersecting the bending line.

3. The flexible substrate according to claim 1,
wherein the base material is curved at a part between the first end and the second end,
wherein the base material has the bending line at the curved part,
wherein the first conductive pattern is curved along the curved shape of the base material, and
wherein the second conductive pattern has a straight line shape in a partial section across the bending line.

4. The flexible substrate according to claim 2,
wherein the base material is curved at a part between the first end and the second end,
wherein the base material has the bending line at the curved part,
wherein the first conductive pattern is curved along the curved shape of the base material, and
wherein the second conductive pattern has a straight line shape in a partial section across the bending line.

5. An electronic device comprising:
the flexible substrate according to claim 1;
the first substrate that is connected to the first end of the flexible substrate; and
the second substrate that is connected to the second end of the flexible substrate.

6. An electronic device comprising:
the flexible substrate according to claim 2;
the first substrate that is connected to the first end of the flexible substrate; and
the second substrate that is connected to the second end of the flexible substrate.
